(19) United States
(12) Patent Application Publication
(10) Pub. No.: US 2024/0046867 A1
(43) Pub. Date: Feb. 8, 2024

(54) BEZEL FREE MICROLED DISPLAY FOR SMART GLASS APPLICATIONS

(71) Applicant: GM Global Technology Operations LLC, Detroit, MI (US)

(72) Inventors: Julien P. Mourou, Bloomfield Hills, MI (US); Susan Carol Ellis, Hampton (CA); Jonglee Park, Troy, MI (US)

(21) Appl. No.: 17/880,268

(22) Filed: Aug. 3, 2022

(51) Int. Cl. G09G 3/3233

(52) U.S. Cl. CPC G09G 3/3233; G09G 2300/0426

(57) ABSTRACT

A vehicle includes a window and a display for the window. The window includes a first pane, a second pane. The display is disposed between the first pane and the second pane. The display includes an active region, a bus region having bus lines for supplying a current to the active region, the bus region having a first line density, and a border to the bus region, the border including the bus lines and having a second line density.

### INTRODUCTION

The subject disclosure relates to window displays and, in particular, to a display having bus lines organized for shape design.

A window of a vehicle can include a transparent display that can display information. A transparent display generally includes a plurality of microLEDs which are invisible until they are turned on and a plurality of bus lines that provide signals to the microLEDS. One concern is that the bus lines themselves are visible to a viewer and provides a distraction. Accordingly, it is desirable to organize the bus lines in a manner that reduces the distraction to the viewer.

### SUMMARY

In one exemplary embodiment, a display for a window is disclosed. The display includes an active region, a bus region having bus lines for supplying a current to the active region, the bus region having a first line density, and a border to the bus region, the border including the bus lines and having a second line density.

In addition to one or more of the features described herein, the first line density is a uniform line density. The bus region includes a dummy bus line to maintain a uniform line density throughout the bus region. In an embodiment, a bus line includes a first section having a first diameter and a second section having a second diameter. The active region and the bus lines are formed on a substrate, wherein a first shape of the border is the same as a second shape of the substrate. The active region includes LEDs arranged to form an area having a non-rectangular perimeter. The border has a non-rectangular shape.

In another exemplary embodiment, a window is disclosed. The window includes a first pane, a second pane, and a display disposed between the first pane and the second pane. The display includes an active region, a bus region having bus lines for supplying a current to the active region, the bus region having a first line density, and a border to the bus region, the border including the bus lines and having a second line density.

In addition to one or more of the features described herein, the first line density is a uniform line density. The bus region includes a dummy bus line to maintain a uniform line density throughout the bus region. In an embodiment, a bus line includes a first section having a first diameter and a second section having a second diameter. The active region and the bus lines are formed on a substrate, wherein a first shape of the border is the same as a second shape of the substrate. The active region includes LEDs arranged to form an area having a non-rectangular perimeter. The border has a non-rectangular shape.

In yet another exemplary embodiment, a vehicle is disclosed. The vehicle includes a window having a display disposed thereon. The display includes an active region, a bus region having bus lines for supplying a current to the active region, the bus region having a first line density, and a border to the bus region, the border including the bus lines and having a second line density.

In addition to one or more of the features described herein, the first line density is a uniform line density. The bus region includes a dummy bus line to maintain a uniform line density throughout the bus region. In an embodiment, a bus line includes a first section having a first diameter and a second section having a second diameter. The active region and the bus lines are formed on a substrate, wherein a first shape of the border is the same as a second shape of the substrate. The active region includes LEDs arranged to form an area having a non-rectangular perimeter.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 shows a side of a vehicle in an illustrative embodiment;

FIG. 2 shows a viewing area of the display, in an illustrative embodiment;

FIG. 3 shows an image of the viewing area, in an illustrative embodiment;

FIG. 4 shows an image of the viewing area in another illustrative embodiment;

FIG. 5 shows an image of the viewing area in another illustrative embodiment; and

FIG. 6 shows an image of the viewing area in another illustrative embodiment.

### DETAILED DESCRIPTION

The following description is merely exemplary in nature and is not intended to limit the present disclosure, its application or uses. It should be understood that throughout the drawings, corresponding reference numerals indicate like or corresponding parts and features.

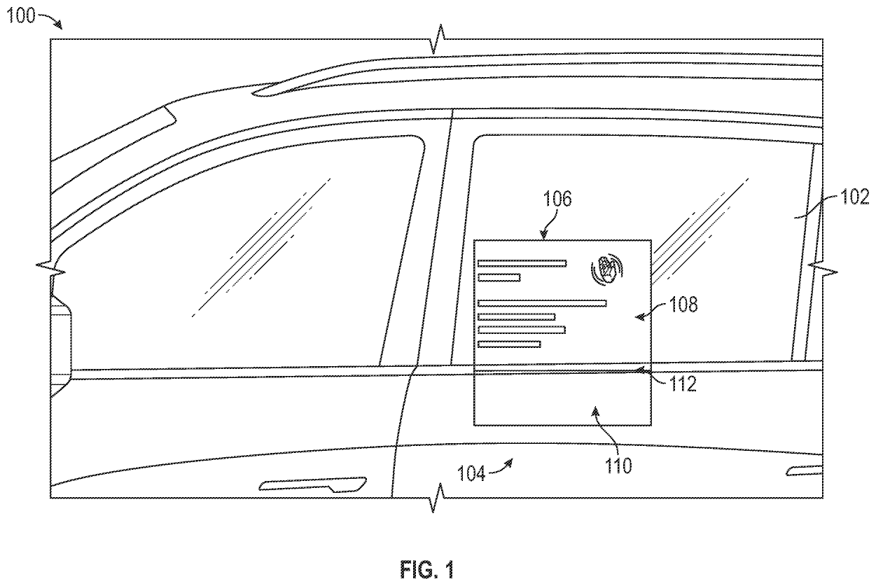

In accordance with an exemplary embodiment, FIG. 1 shows a side of a vehicle 100. The vehicle 100 includes a window 102. The window 102 is a transparent or semi-transparent material that is supported in place by a frame 104, which is generally opaque. In various embodiments, the frame 104 is a door of the vehicle 100 and the window 102 can be opened by rolling it down into the door or closed by it rolling up out of the door. However, the frame 104 can be any suitable supporting structure. The window 102 includes a display 106. The display 106 is thin-film device that and can be attached to a surface of the window 102 or disposed or embedded between a first pane and a second pane of the window. The display 106 includes a viewing area 108 and a driver area 110. The viewing area 108 includes an array of pixels which can be activated to create an image. The driver area 110 includes driving circuits that control activation of the pixels of the viewing area 108 to display the image by providing electrical signals along electrical wires to each of the pixels. The driver area 110 is separated from the viewing area 108 by a dividing line 112. When the window 102 is rolled up to its maximum extent, the dividing line 112 lies along an interface between the window 102 and the frame 104 so that the driver area 110 remains hidden behind the frame 104. This driver area 110 is hidden for aesthetic reasons.

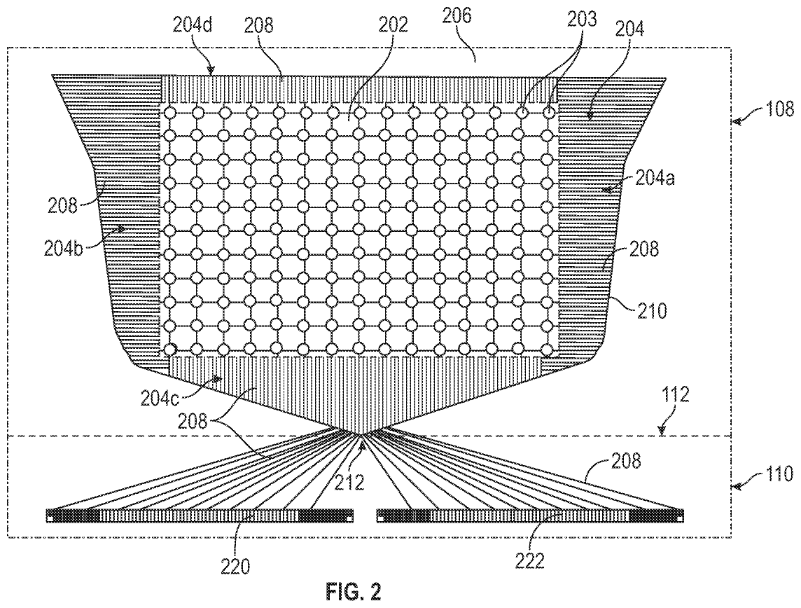

FIG. 2 shows a viewing area 108 of the display 106, in an illustrative embodiment. The viewing area 108 includes an active region 202 a bus region 204 and an empty space region 206, which generally surrounds the bus region 204. The active region 202 includes a plurality of light emitting diodes (LEDs) 203 which can be turned on or off in order to present information to a viewer. The bus region 204 includes bus lines 208 that supply current or a signal to the plurality of LEDs in the active region 202. As shown in FIG. 2, the bus region 204 surrounds the active region 202 on all sides. However, this is not meant to be a limitation of the invention. In alternate embodiments, the bus region 204 does not surround all sides of the active region 202.

A border 210 separates the bus region 204 from the empty space region 206. In the driver area 110, the bus lines 208 extend from one of a source driver 220 or a gate driver 222. The bus lines 208 extending from the source driver 220 extend along a horizontal direction when delivering its signal to the LEDs in the active region 202. The bus lines 208 extending from the gate driver 222 extend along a vertical direction when delivering its signals to the LEDs in the active region 202. From the driver area 110, the bus lines 208 enter the viewing area 108 at a point of entry 212. The point of entry 212 is generally located at the dividing line 112. The point of entry 212 can have an extended horizontal length along the dividing line 112. Although a single point of entry 212 is shown for illustrative purposes, it is to be understood that there can be more than one point of entry 212 in various embodiments. From the point of entry 212, the bus lines 208 run along the border 210. At an appropriate location along the border 210, a selected bus line 208 separates from the border 210 and extends through the bus region 204 and into the active region 202. The appropriate location generally corresponds to a horizontal location or vertical location of a pixel associated with the selected bus line.

A unit area (i.e., square centimeter, square inch, etc.) within the viewing area 108 can have an associated line density. The line density indicates a number bus lines within the unit area. The bus region 204 has a first line density and the border 210 has a second line density. The first line density can be different from the second density and is generally less than the second line density. Since the line density of a unit area affects the transparency of the unit area, a first transparency of the bus region 204 is generally greater than the transparency of the border 210. Stated differently, the border 210 is more opaque than the bus region 204. In various embodiments, the border 210 makes an outline of the bus region 204 that is intentionally visible to a viewer. The border 210 can by styled to form a frame about the active region 202 for aesthetic purposes. The border 210 can be styled in any suitable shape (e.g., a manufacturer's logo).

The first line density can be a uniform line density throughout the bus region 204. The bus region 204 can include a plurality of sections, with each section including bus lines that extend in a same general direction, such as a horizontal direction or a vertical direction. For illustrative purposes, the bus region 204 of FIG. 2 includes a first section 204a and a second section 204b having horizontal lines and a third section 204c and a fourth section 204d having vertical lines. The bus lines of the first section 204a and the third section 204c are active lines used in the delivery of signals to the active region 202. To control LEDs in the active region 202, the display generally includes horizontal bus lines that provide scan signals for passive matrix driving and gate signal for active matrix driving as well as vertical bus lines that provide data signals for passive matrix driving and source signals for active matrix driving. The arrangement of these bus lines 208 can introduce areas of low line density and high line density in the bus region 204. The bus lines of the second section 204b and the fourth section 204d however may not be necessary for delivering signals to the active area. Bus lines in these sections can be dummy bus lines which are inactive and carry no signals. Dummy bus lines can be placed in these sections to maintain a uniform line density throughout the bus region 204. This can be done for aesthetic or design purposes. A dummy bus line can also be employed within any given section (e.g., first section 204a) in order to reduce or eliminate any differences in line density in different areas of the section.

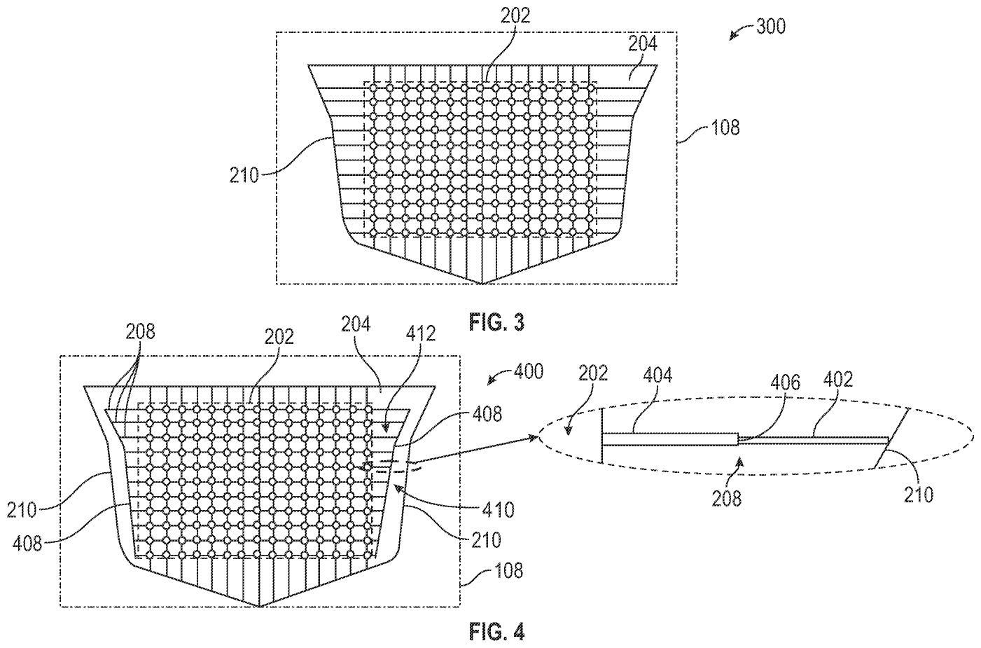

FIG. 3 shows an image 300 of the viewing area 108, in an illustrative embodiment. The border 210 has a line density that makes it visible to the viewer. The line density of the bus region 204 is less than the line density of the border 210, allowing the bus region to be more transparent than the border. When the active region 202 is turned off, the border 210 can be the only part of the viewing area 108 that is noticed by the viewer. The border 210 is designed to have a non-standard shape (i.e., a non-rectangular shape). In various embodiments, the border 210 is designed to have aesthetically pleasing shape or a commercially representative shape, such as a brand logo.

FIG. 4 shows an image 400 of the viewing area 108 in another illustrative embodiment. The bus region 204 has a uniform shape density. A bus line 208 can have a first length 402 having a first diameter or first thickness and a second length 404 having a second diameter or second thickness. As an example, the first density and the second density can be such that the first length 402 is less visible to the viewer than the second length 404. The first length 402 and the second length 404 meet at an interface 406. A plurality of bus lines 208 can therefore be arranged so that their interfaces 406 define a contour 408. The contour 408 defines a first section 410 of the bus region 204 and a second section 412 of the bus region. The first section 410 is more or less transparent than the second section 412. In this manner, the contour 408 can be designed to have any desired shape, such as shown in FIG. 4.

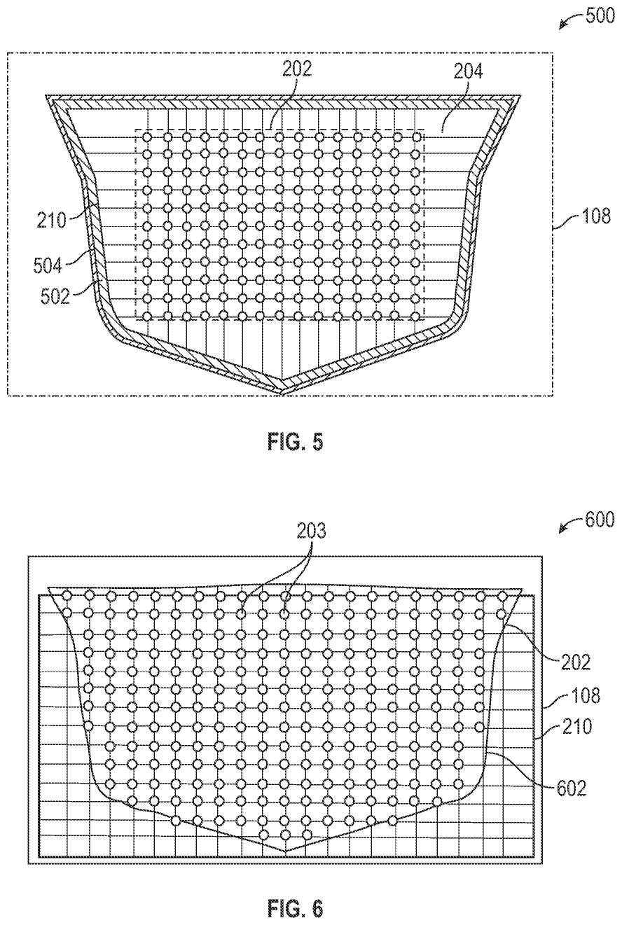

FIG. 5 shows an image 500 of the viewing area 108 in another illustrative embodiment. The active region 202, bus region 204 and border 210 are formed on a substrate 502. The substrate 502 can be useful for blocking infrared light, etc. The substrate 502 can have a perimeter 504 in the shape of any desired design. As shown in FIG. 5, the border 210 has a first shape and the substrate 502 has a second shape that is the same as the first shape. In alternate embodiments, he first shape can be different from the second shape.

FIG. 6 shows an image 600 of the viewing area 108 in another illustrative embodiment. The LEDs 203 of the active region 202 are arranged so that the perimeter of the active region forms a desired shape 602 (i.e., a non-rectangular perimeter).

In various embodiments, the illustrative embodiments of FIGS. 3-6 can be used individually or in any suitable combination.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

1. A display for a window, comprising:
an active region having an array of light emitting diodes;
a bus region having bus lines for supplying a current to the array of light emitting diodes of the active region, the bus region having a first line density; and
a border to the bus region, the border including the bus lines and having a second line density.

2. The display of claim 1, wherein the first line density is a uniform line density.

3. The display of claim 2, wherein the bus region includes a dummy bus line to maintain a uniform line density throughout the bus region.

4. The display of claim 1, wherein a bus line includes a first section having a first diameter and a second section having a second diameter.

5. The display of claim 1, wherein the active region and the bus lines are formed on a substrate, wherein a first shape of the border is the same as a second shape of the substrate.

6. The display of claim 1, wherein the active region includes LEDs arranged to form an area having a non-rectangular perimeter.

7. The display of claim 1, wherein the border has a non-rectangular shape.

8. A window, comprising:
a first pane;
a second pane;
a display disposed between the first pane and the second pane, the display comprising:
an active region having an array of light emitting diodes;
a bus region having bus lines for supplying a current to the array of light emitting diodes of the active region, the bus region having a first line density; and
a border to the bus region, the border including the bus lines and having a second line density.

9. The window of claim 8, wherein the first line density is a uniform line density.

10. The window of claim 9, wherein the bus region includes a dummy bus line to maintain a uniform line density throughout the bus region.

11. The window of claim 8, wherein a bus line includes a first section having a first diameter and a second section having a second diameter.

12. The window of claim 8, wherein the active region and the bus lines are formed on a substrate, wherein a first shape of the border is the same as a second shape of the substrate.

13. The window of claim 8, wherein the active region includes LEDs arranged to form an area having a non-rectangular perimeter.

14. The window of claim 8, wherein the border has a non-rectangular shape.

15. A vehicle, comprising:
a window having a display disposed thereon, the display comprising:
an active region;
a bus region having bus lines for supplying a current to the active region, the bus region having a first line density; and
a border to the bus region, the border including the bus lines and having a second line density.

16. The vehicle of claim 15, wherein the first line density is a uniform line density.

17. The vehicle of claim 16, wherein the bus region includes a dummy bus line to maintain a uniform line density throughout the bus region.

18. The vehicle of claim 15, wherein a bus line includes a first section having a first diameter and a second section having a second diameter.

19. The vehicle of claim 15, wherein the active region and the bus lines are formed on a substrate, wherein a first shape of the border is the same as a second shape of the substrate.

20. The vehicle of claim 15, wherein the active region includes LEDs arranged to form an area having a non-rectangular perimeter.
